(19) United States
(12) Patent Application Publication
(10) Pub. No.: US 2010/0319979 A1
(43) Pub. Date: Dec. 23, 2010

(54) PRINTED CIRCUIT BOARD AND METHOD FOR DRILLING HOLE THEREIN

(75) Inventor: SHOU-KUO HSU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/541,139

(22) Filed: Aug. 13, 2009

(30) Foreign Application Priority Data
Jun. 17, 2009 (CN) 200910303332.6

(51) Int. Cl. H05K 1/11; B23B 35/00

(52) U.S. Cl. 174/262; 408/1 R

(57) ABSTRACT

A method for defining a stepped hole in a printed circuit board (PCB) by drilling layers of the PCB by different sized drill bits along a same axis. The stepped hole in the layers of the PCB are decreased in diameters sequentially.

### BACKGROUND

1. Technical Field

The present disclosure relates to circuit boards, and more particularly to a printed circuit board (PCB) with stepped holes, and a method for drilling the stepped holes.

2. Description of Related Art

In a multilayer PCB, vias may be defined to provide electrical connections between copper traces on different layers of the PCB. A via may include a cylindrical plated hole, and pads encircling the plated hole in the different layers of the PCB to solder connections of components of the PCB. A proper proportion of a diameter of each of the pads to a diameter of the cylindrical plated hole needs to satisfy required impedance. Sometimes, the proper proportion may not be achieved because the diameters of the pads are changeable to suit components in different sizes, while the diameters of the cylindrical plated holes are constant. Therefore, the required impedance may be not acquired.

### BRIEF DESCRIPTION OF THE DRAWINGS

FIG. 1 is a cross-sectional view of an embodiment of a printed circuit board (PCB) with a stepped hole.

FIG. 2 is a flowchart diagram of an embodiment of a method for drilling the stepped hole of FIG. 1.

FIGS. 3A-3F are cross-sectional views of the PCB of FIG. 1 in different states of drilling the stepped hole.

### DETAILED DESCRIPTION

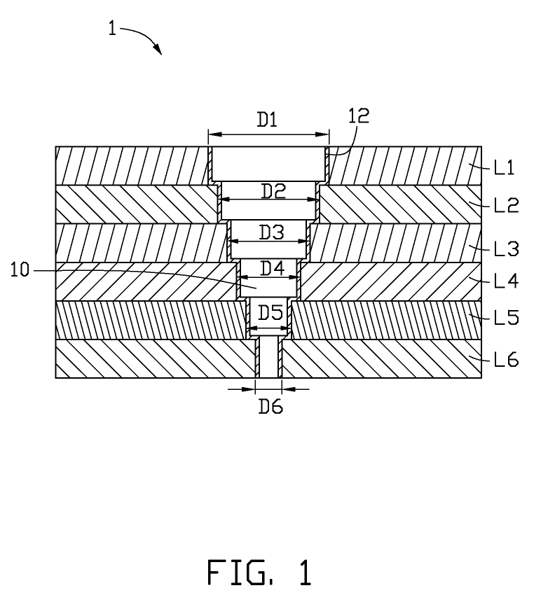

Referring to FIG. 1, an embodiment of a printed circuit board (PCB) 1 includes at least two layers and a via. In this embodiment, the at least two layers include a plurality of layers L1-L6. The layers L1-L6 are laminated together. The via includes a stepped hole 10 defined through the layers L1-L6. A conductive sheet 12 plates the sidewall bounding the stepped hole 10. The conductive sheet 12 may be made of copper, aluminum, or other metal.

In the illustrated embodiment, the diameter of the stepped hole 10 is different at each of the layers L1-L6 and is denoted as diameters D1-D6, respectively. Relationships of the diameters D1-D6 are expressed as D1>D2>D3>D4>D5>D6, i.e., they are decreased sequentially.

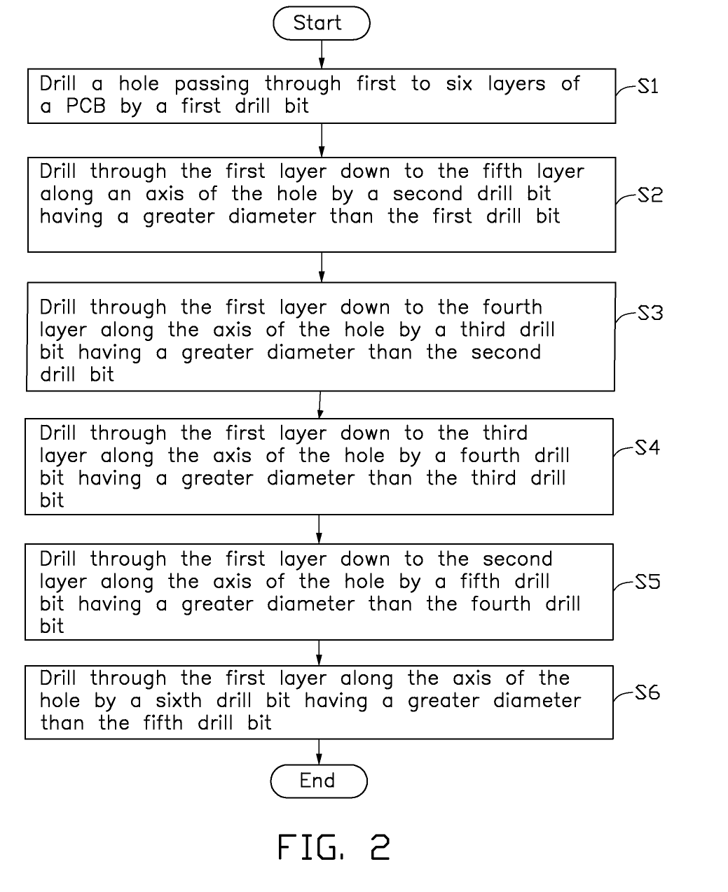

Referring to FIG. 2, an embodiment of a method for defining the stepped hole 10 in the PCB 1 of FIG. 1 includes the following steps.

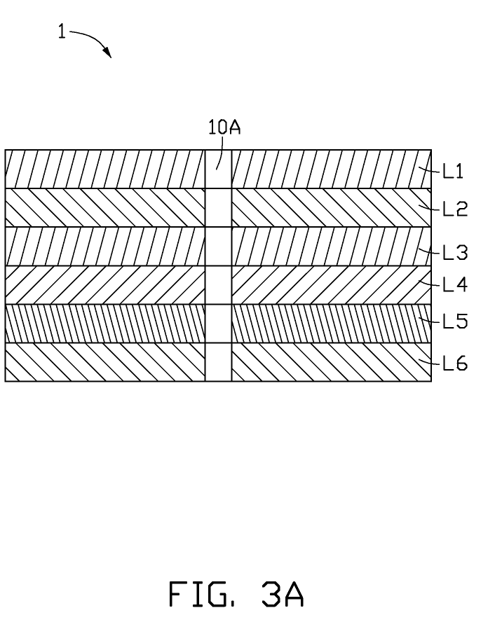

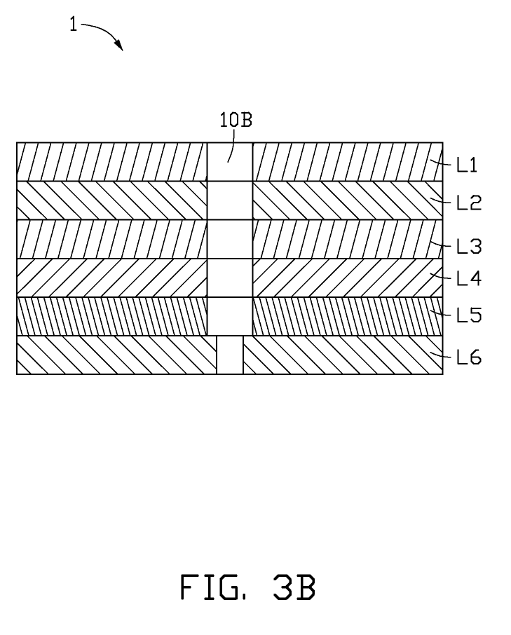

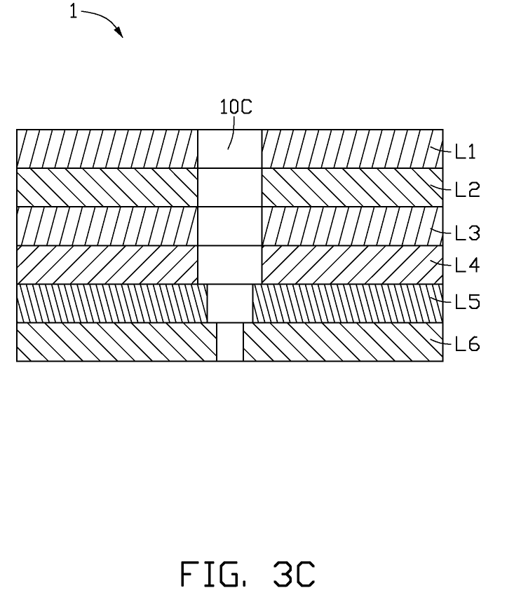

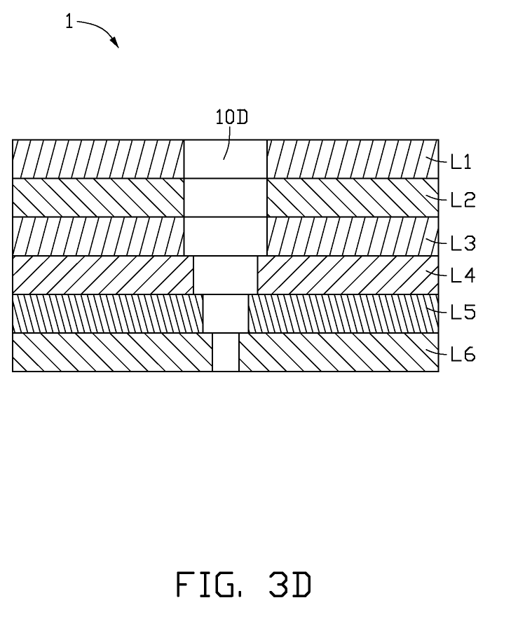

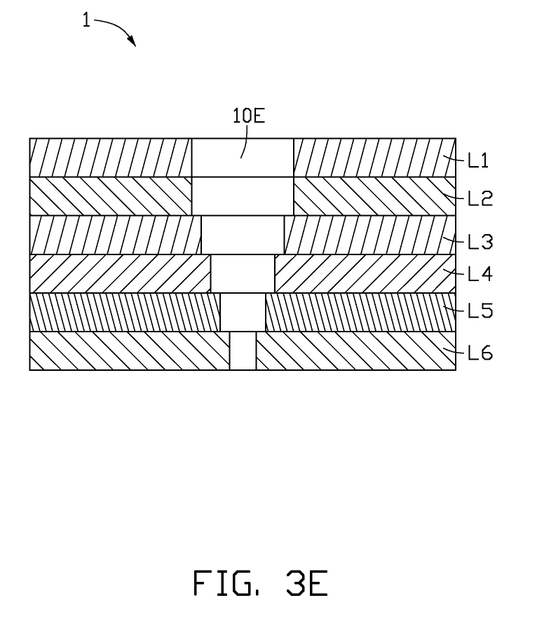

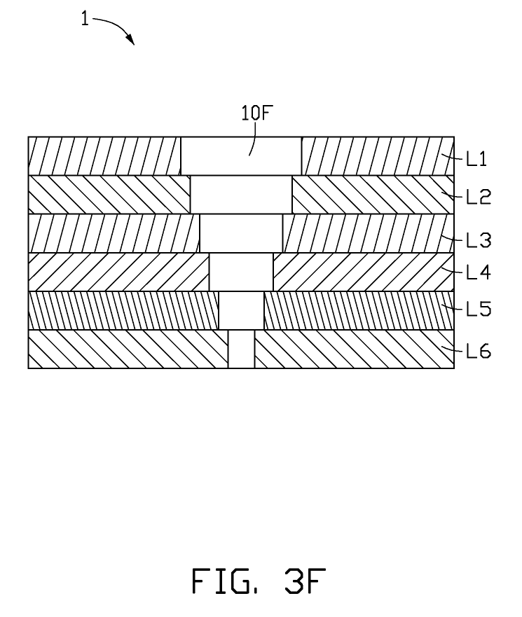

In step 1, a hole 10A as shown in FIG. 3A is defined in the PCB 1 through the plurality of layers L1-L6, via drilling through the layer L1 down to the layer L6 with a first drill bit. A diameter of the first drill bit is D6, therefore, a diameter of the hole 10A is D6.

In step 2, a hole 10B as shown in FIG. 3B is defined in the PCB 1 through the layers L1-L5, via drilling though the layer L1 down to the layer L5 coaxially aligned with the hole 10A, using a second drill bit. A diameter of the second drill bit is D5. Therefore, a diameter of the hole 10B through the layers L1-L5 is D5.

In step 3, a hole 10C as shown in FIG. 3C is defined in the PCB 1 through the layers L1-L4, via drilling though the layer L1 down to the layer L4 coaxially aligned with the hole 10B, by a third drill bit. A diameter of the third drill bit is D4. Therefore, a diameter of the hole 10C in the layers L1-L4 is D4.

In step 4, a hole 10D as shown in FIG. 3D is defined in the PCB 1 through the layers L1-L3, via drilling though the layer L1 down to the layer L3 coaxially aligned with the hole 10C, by a fourth drill bit. A diameter of the fourth drill bit is D3. Therefore, a diameter of the hole 10D in the layers L1-L3 is D3.

In step 5, a hole 10E as shown in FIG. 3E is defined in the PCB 1 through the layers L1 and L2, via drilling though the layer L1 down to the layer L2 coaxially aligned with the hole 10D, by a fifth drill bit. A diameter of the fifth drill bit is D2. Therefore, a diameter of the hole 10E in the layers L1 and L2 is D2.

In step 6, a hole 10F as shown in FIG. 3F is drilled in the layer L1 of the PCB 1, coaxially aligned with the hole 10E, by a sixth drill bit. A diameter of the sixth drill bit is D1. Therefore, a diameter of the hole 10F in the layer L1 is D1. The hole 10F in the layer L1, the hole 10E in the layer L2, the hole 10D in the layer L3, the hole 10C in the layer L4, the hole 10B in the layer L5, and the hole 10A in the layer L6 communicate in that order, to form the stepped hole 10.

Holes at different depths can be defined in the PCB 1 according to need, for example, a stepped hole may be defined only in the layers L1-L4 without drilling the layers L5 and L6. The diameters D1-D6 of the stepped hole 10 can be predetermined according to need, such as required impedance of the via in the layers L1-L6. For example, the diameters D1 and D6 of the stepped hole 10 can be predetermined according to sizes of pads which are respectively formed on the layers L1 and L6 to provide an electronic connection between the layers L1 and L6 via the stepped hole 10.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A printed circuit board, comprising:
a first layer; and
a second layer located under the first layer;
wherein a hole is defined in the printed circuit board through the first and second layers, wherein a diameter of the hole at the first layer is greater than a diameter of the hole at the second layer.

2. The printed circuit board of claim 1, wherein a conductive sheet plates the sidewall bounding the hole.

3. The printed circuit board of claim 2, wherein the conductive sheet is made of copper or aluminum.

4. A printed circuit board, comprising:
a plurality of layers laminated with one another;
wherein a hole is defined in the printed circuit board through the plurality of layers, wherein diameters of the hole at each of the plurality of layers are decreased sequentially.

5. A method for drilling a hole in a printed circuit board comprising a first layer and a second layer adjacent to the first layer, the method comprising:
drilling a first hole through the first layer and the second layer; and
drilling a second hole through the first layer coaxially aligned with the first hole, wherein a diameter of the second hole is greater than a diameter of the first hole.
